(19) United States
(12) Patent Application Publication
(10) Pub. No.: US 2021/0319987 A1
(43) Pub. Date: Oct. 14, 2021

(54) EDGE RING, STAGE AND SUBSTRATE PROCESSING APPARATUS

(71) Applicant: Tokyo Electron Limited, Tokyo (JP)

(72) Inventors: Ryo CHIBA, Miyagi (JP); Akira NAGAYAMA, Miyagi (JP); Yasuharu SASAKI, Miyagi (JP); Daiki SATOH, Miyagi (JP); Taketoshi TOMIOKA, Miyagi (JP)

(21) Appl. No.: 17/220,085

(22) Filed: Apr. 1, 2021

(30) Foreign Application Priority Data
Apr. 8, 2020 (JP) 2020-069797

(51) Int. Cl. H01J 37/32; C23C 16/455; H01L 21/683; H01L 21/67

(52) U.S. Cl. CPC H01J 37/32642; H01J 37/32715; C23C 16/45591; H01L 21/67069; H01J 2237/3321; H01J 2237/2007; H01J 2237/3341; H01L 21/6831

(57) ABSTRACT

An edge ring to be disposed to encircle a substrate is provided. The edge ring includes a bottom used to define vertical heights that are from points on the circumference of a virtual circle, to the bottom of the edge ring, the virtual circle having a radius from a first point that is placed on a central axis of the edge ring, the first point being defined as the center of the virtual circle, the radius being half of a diameter ranging from an inner diameter to an outer diameter of the edge ring, and an absolute value indicative of a difference between a maximum value and a minimum value for the vertical heights being set to be less than or equal to a preset upper limit.

### CROSS-REFERENCE TO RELATED APPLICATION

This patent application claims priority to Japanese Patent Application No. 2020-069797, filed Apr. 8, 2020, the entire contents of which are incorporated herein by reference in their entirety.

### TECHNICAL FIELD

The present disclosure relates to an edge ring, a stage, and a substrate processing apparatus.

### BACKGROUND

In substrate processing apparatuses, edge rings are provided around outer edges of substrates to be mounted on electrostatic chucks, so as to surround the substrates. When plasma processes are performed in chambers, the edge rings converge plasmas toward surfaces of the substrates, thereby improving efficiency of a wafer process.

In general, the edge ring is formed of silicon (Si), and a slope of a silicon bottom of the edge ring is adjusted from a non-inclined condition under which the silicon bottom of the edge ring is flat, to an inclined condition under which the slope of the silicon bottom of the edge ring corresponds to ± a few micrometers at highest point. In recent years, for purposes of increasing a long life of the edge ring, material with increased stiffness, as typified by silicon carbide (SiC), is adopted as material of the edge ring.

Heat transfer gases such as helium (He) gas are supplied between the bottom of the edge ring, which is disposed on a mounting surface along the outer periphery of the electrostatic chuck, and the mounting surface of the electrostatic chuck, and thus a temperature of the edge ring is adjusted. For example, Unexamined Japanese Patent Application Publication No. 2016-122740, which is hereafter referred to as Patent document 1, proposes electrostatically attracting a wafer during loading and unloading of the wafer and wafer-less dry cleaning (WLDC), in order to reduce a maximum amount (leakage amount) of the heat transfer gas that leaks from a space between the edge ring and the mounting surface of the electrostatic chuck.

### SUMMARY

According to one aspect of the present disclosure, an edge ring to be disposed to encircle a substrate is provided. The edge ring includes a bottom used to define vertical heights that are from points on the circumference of a virtual circle, to the bottom of the edge ring, the virtual circle having a radius from a first point that is placed on a central axis of the edge ring, the first point being defined as the center of the virtual circle, a diameter of the virtual circle ranging from an inner diameter to an outer diameter of the edge ring, and an absolute value indicative of a difference between a maximum value and a minimum value for the vertical heights being set to be less than or equal to a preset upper limit.

### BRIEF DESCRIPTION OF THE DRAWINGS

FIG. 1 is a cross-sectional view schematically illustrating an example of a substrate processing apparatus according to one embodiment;

FIGS. 2A and 2B are diagrams illustrating an example of the configuration of peripheral components of an edge ring according to one embodiment;

FIGS. 3A and 3B are diagrams schematically illustrating an example of waviness in a circumferential direction of the bottom of the edge ring according to one embodiment;

FIG. 4 is a diagram illustrating an example of the correlation between the waviness and a leakage amount of a heat transfer gas according to one embodiment;

FIGS. 5A and 5B are diagrams schematically illustrating an example of waviness in a circumferential direction of an edge-ring mounting surface of a stage according to a second embodiment; and

FIG. 6 is a diagram schematically illustrating an example of spaces between the bottom of the edge ring and the edge-ring mounting surface of the stage according to a third embodiment.

### DETAILED DESCRIPTION

One or more embodiments of the present disclosure will be described with reference to the drawings. In each drawing, the same numerals denote the same components, and duplicate description for the components may be omitted.

[Configuration of Substrate Processing Apparatus]

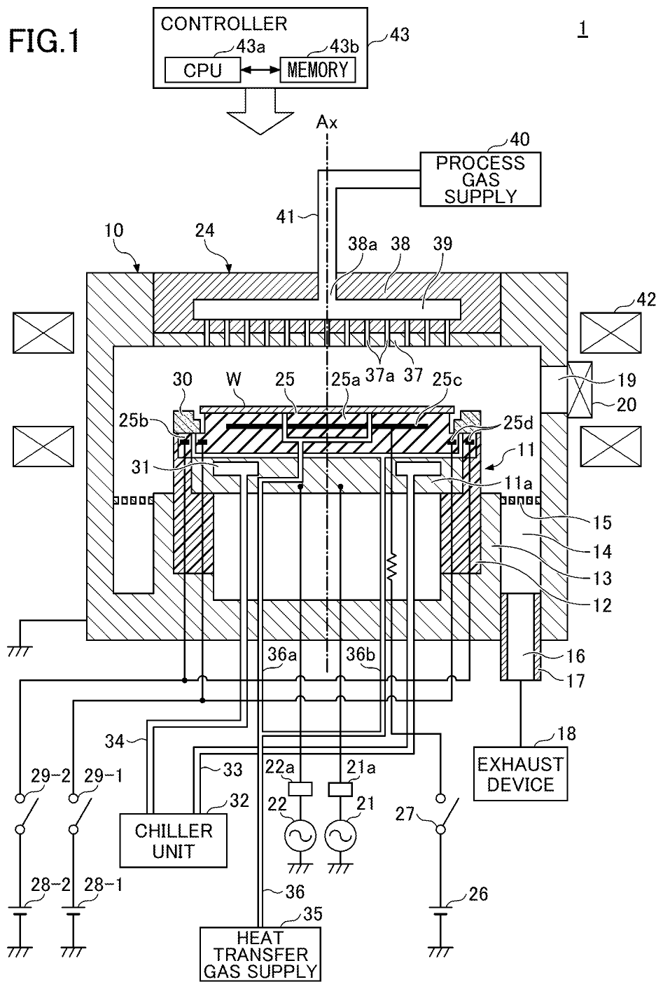

A substrate processing apparatus 1 according to one embodiment will be described with reference to FIG. 1. FIG. 1 is a cross-sectional view schematically illustrating an example of the substrate processing apparatus 1 according to one embodiment. The present embodiment will be described using an example of an RIE (Reactive-Ion Etching) substrate processing apparatus. However, the substrate processing apparatus 1 is not limited to the example described above, and may be applied to an apparatus such as a plasma etching apparatus or a plasma chemical vapor deposition (CVD) apparatus, which uses surface wave plasmas.

The substrate processing apparatus 1 includes a metallic process chamber 10 having a cylindrical shape, for example. A process compartment in which a plasma process such as a plasma etch or plasma CVD is performed is provided in the process chamber 10. The process chamber 10 is formed of aluminum or stainless steel, and is grounded.

A disk-shaped stage (bottom electrode) 11 for mounting a substrate W is disposed in the process chamber 10. A wafer is an example of the substrate W. The stage 11 includes a base 11a, and an electrostatic chuck 6 is provided on the base 11a. For example, the base 11a is formed of aluminum. The base 11a is supported by a cylindrical support 13 through an insulating cylindrical holder 12, and the support 13 extends upward in a vertical direction, from the bottom of the process chamber 10.

An exhaust passage 14 is provided between a sidewall of the process chamber 10 and the cylindrical support 13. An annular baffle plate 15 is disposed at an inlet or a midway location of the exhaust passage 14, and an exhaust port 16 is provided at a bottom portion of the exhaust passage 14. An exhaust device 18 is connected to the exhaust port 16 through an exhaust pipe 17. The exhaust device 18 has a vacuum pump to depressurize a process space in the process chamber 10, up to a predetermined vacuum level. The exhaust pipe 17 has an automatic pressure control valve (hereafter referred to as APC) that is a variable butterfly valve. In the APC, a pressure control of the process chamber 10 is performed. A gate valve 20 for opening or closing a loading port 19 for the substrate W is attached to a sidewall of the process chamber 10.

A first radio frequency source 21 for plasma formation and RIE is electrically connected to the base 11a via a matching device 21a. The first radio frequency source 21 applies radio frequency power with a first frequency to the base 11a. For example, the first frequency is 40 MHz.

A second radio frequency source 22 for applying a bias voltage is electrically connected to the base 11a via a matching device 22a. The second radio frequency source 22 applies radio frequency power with a second frequency that is lower than the first frequency, to the base 11a. For example, the second frequency is 3 MHz.

A gas showerhead 24 is provided in a top wall of the chamber 1. The gas showerhead 24 serves as a top electrode that is set at a ground potential, as described below. In such a manner, the radio frequency power output from the first radio frequency source 21 is applied to a portion between the stage 11 and the gas showerhead 24.

An electrostatic chuck 25 is disposed on the top of the stage 11. The electrostatic chuck 25 attracts the substrate W by an electrostatic attractive force. The stage 11 shares a central axis Ax with the process chamber 10. In this example, a central axis of the stage 11 is approximately the same as the central axis Ax of the process chamber 10. The electrostatic chuck 25 includes a disk-shaped central portion 25a for mounting the substrate W, and includes an annularly peripheral portion 25b. There is a level difference between the central portion 25a and the peripheral portion 25b, and the central portion 25a is thicker than the peripheral portion 25b. An edge ring 30 encircling the outer edge of the substrate W is mounted on an edge-ring mounting surface that is the top of the peripheral portion 25b. The edge ring 30 is also referred to as a focus ring. The edge ring 30 shares the central axis Ax with the process chamber 10. In this example, a central axis of the edge ring 30 is approximately the same as the central axis Ax of the process chamber 10.

The central portion 25a of the electrostatic chuck 25 is configured by sandwiching an electrode plate 25c between a pair of dielectric films, and the electrode plate 25c is formed of a conductive film. The peripheral portion 25b is configured by sandwiching an electrode plate 25d between a pair of dielectric films. The electrode plate 25d is formed of a conductive film. The electrode plate 25c is electrically connected to a direct current (DC) power source 26 via a switch 27. A DC power source 28-1 is electrically connected to the electrode plate 25d via a switch 29-1, and a DC power source 28-2 is electrically connected to the electrode plate 25d via a switch 29-2. When the DC power source 26 applies a DC voltage to the electrode plate 25c, the electrostatic chuck 25 uses a resulting coulomb force to attract the substrate W. Also, when the DC power sources 28-1 and 28-2 each apply a DC voltage to the electrode plate 25d, the electrostatic chuck 25 uses a resulting coulomb force to attract the edge ring 30.

For example, an annular coolant compartment 31 that extends in a circumferential direction of the stage 11 is provided in the stage 11. A chiller unit 32 circulates a coolant having a predetermined temperature, through pipes 33 and 34, and thus the coolant is supplied to the coolant compartment 31. The temperature of the substrate W on the electrostatic chuck 25 is adjusted in accordance with the temperature of the coolant. Cooling water is an example of the coolant.

A heat transfer gas supply 35 is connected to a gas supply line 36. The gas supply line 36 bifurcates into a wafer-side line 36a and an edge ring-side line 36b. The wafer-side line 36a reaches the central portion 25a of the electrostatic chuck 25, and the edge ring-side line 36b reaches the peripheral portion 25b.

The heat transfer gas supply 35 employs the wafer-side line 36a to supply the heat transfer gas to a space between a substrate-mounting portion of the central portion 25a of the electrostatic chuck 25 and the bottom of the substrate W. Gas having thermal conductivity, such as helium (He) gas, is preferably used as the heat transfer gas.

The gas showerhead 24 provided in the top wall of the process chamber 10 includes an electrode plate 37 situated at the bottom of the gas showerhead. The gas showerhead 24 also includes an electrode support 38 that removably supports the electrode plate 37. The electrode plate 37 has gas holes 37a. A buffer compartment 39 is provided in an interior of the electrode support 38. A process gas supply 40 is connected to a gas inlet 38a via a gas supply line 41.

Components of the substrate processing apparatus 1 are each connected to a controller 43. The controller 43 controls each component of the substrate processing apparatus 1. The above components include the exhaust device 18, the first radio frequency power source 21, the second radio frequency power source 22, and the switches 27, 29-1, and 29-2 for the electrostatic chuck. The components also includes the DC power sources 26, 28-1, and 28-2, the chiller unit 32, the heat transfer gas supply 35, the process gas supply 40, and the like.

The controller 43 includes a central processor unit (CPU) 43a and a memory 43b (storage device). By retrieving a program and recipe from the memory 43b to execute the program and recipe, the controller 43 controls a desired substrate process to be executed at the substrate processing apparatus 1. The controller 43 also controls a process to cause the edge ring 30 to be electrostatically attracted as well as a process to cause the heat transfer gas to be supplied, in accordance with a substrate process.

A magnet 42 extending annularly and concentrically is disposed around the process chamber 10. The magnet 42 causes a horizontal magnetic field to be induced in one direction. A radio frequency (RF) electric field is induced in a vertical direction by radio frequency power that is applied between the stage 11 and the gas showerhead 24. In such a case, in the process chamber 10, magnetron discharge occurs through process gas, and thus a plasma is formed from the process gas, in proximity to the top of the stage 11.

In the substrate processing apparatus during a dry etch process, the gate valve 20 is first open and then a given substrate W to be processed is carried into the process chamber 10. The carried substrate W is mounted on the electrostatic chuck 25. Then, the process gas supply 40 supplies the process gas (for example, C₄F₈ gas having a predetermined flow rate, or a mixture of O₂ gas and Ar gas) to the process chamber 10, and the process space of the process chamber 10 is depressurized by the exhaust device 18 or the like. Further, the first radio frequency power source 21 and the second radio frequency power source 22 supply radio frequency power to the stage 11, and the DC power source 26 applies the DC voltage to the electrode plate 25c. Thus, the substrate W is attracted to the electrostatic chuck 25. Further, the heat transfer gas is supplied to the bottom of the substrate W and the bottom of the edge ring 30. In such a manner, a plasma is formed from the process gas that is supplied to the process chamber 10. In such a manner, a plasma is formed from the process gas that is supplied to the process chamber 10, and thus the substrate W is processed with radicals and ions in the plasma.

[Configuration of Peripheral Components of Edge Ring]

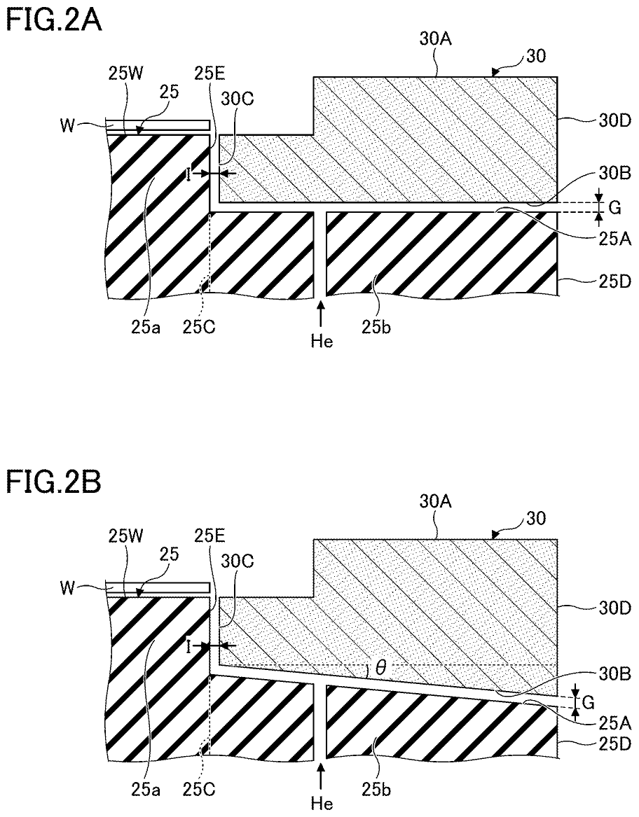

Hereafter, the configuration of the edge ring 30 and peripheral components will be described with reference to FIGS. 2A and 2B. FIGS. 2A and 2B are diagrams illustrating an example of the configuration of peripheral components of the edge ring 30 according to one embodiment. In FIG. 2A, the bottom 30B of the edge ring 30 is formed horizontally, and a given surface provided approximately parallel to the top 30A of the edge ring 30 is ring-shaped. The bottom 30B of the edge ring 30 shares the central axis Ax with the process chamber 10.

The top of the central portion 25a of the electrostatic chuck 25 is a substrate mounting surface 25W on which a given substrate is to be mounted, and the top of the peripheral portion 25b is the edge-ring mounting surface 25A on which the edge ring is mounted. The substrate mounting surface 25W and the edge-ring mounting surface 25A share the central axis Ax with the processing chamber 10. The bottom 30B of the edge ring 30 is provided facing the edge-ring mounting surface 25A of the electrostatic chuck 25, and helium gas is supplied to a gap G between the bottom 30B of the edge ring 30 and the edge-ring mounting surface 25A of the electrostatic chuck 25.

In the following description, a virtual surface that is represented by an extension of a stepped portion 25E of the electrostatic chuck 25 and that marks the border between the central portion 25a and the peripheral portion 25b is referred to as an inner diameter surface 25C of the peripheral portion 25b, for convenience of description. Note, however, that the central portion 25a and the peripheral portion 25b are integral. A space I is provided between the stepped portion 25E and an inner diameter surface 30C of the edge ring 30. The inner diameter surface 30C of the edge ring 30 is located outward by the space I, from the inner diameter surface 25C of the peripheral portion 25b. The outer diameter surface 30D of the edge ring 30 is approximately located along a line extending from the outer diameter surface 25D of the periphery 25b.

As illustrated in FIG. 2A, the edge-ring mounting surface 25A is preferably formed horizontally. However, a peripheral portion of the electrostatic chuck 25 is secured with one or more screws, and thus the edge-ring mounting surface 25A of the electrostatic chuck 25 is inclined downward toward the outer periphery of the electrostatic chuck 25. The edge-ring mounting surface 25A of the electrostatic chuck 25 is inclined at an angle θ with respect to the horizontal direction, as illustrated in FIG. 2B.

When the edge ring 30 is formed of silicon (Si), the bottom 30B of the edge ring 30 has a slope corresponding to a slope of the electrostatic chuck 25. In contrast, when the edge ring 30 is formed of silicon carbide (SiC), deflection of the edge ring 30 is less likely to occur because the silicon carbide is more rigid than silicon. In such a case, the bottom 30B of the edge ring 30 does not have a slope corresponding to the slope of the electrostatic chuck 25, and consequently leakage of the heat transfer gas from the gap G between the edge ring 30 and the edge-ring mounting surface 25A of the electrostatic chuck 25 would occur easily. Accordingly, when the edge ring 30 is formed of silicon carbide, the bottom 30B of the edge ring 30 is inclined at the angle θ so as to have a given slope, as illustrated in FIG. 2B, thereby reducing leakage of the heat transfer gas.

[Edge Ring]

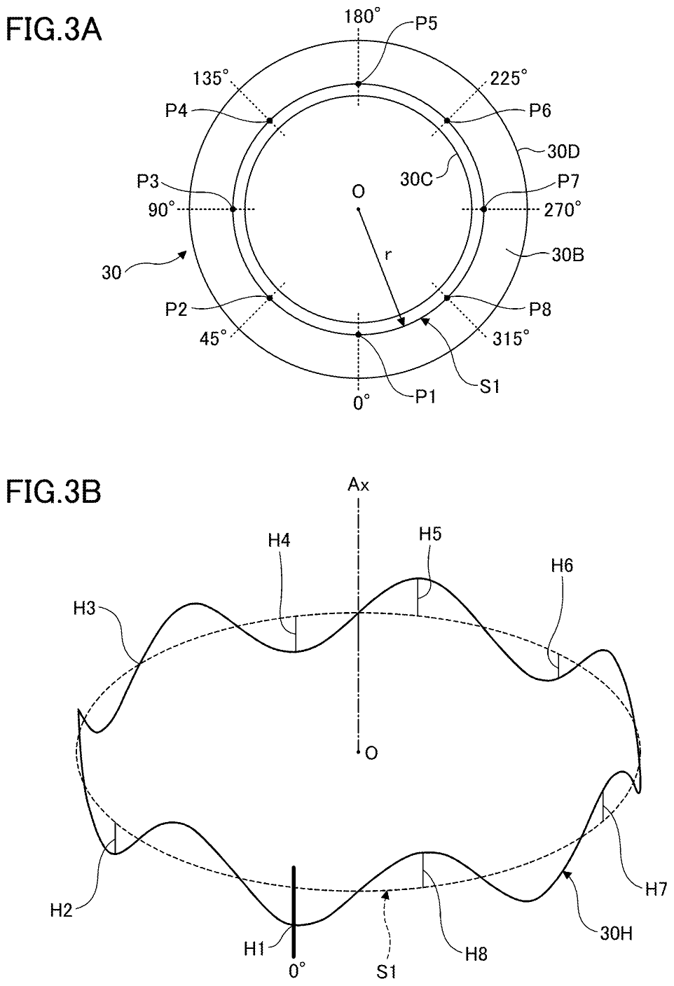

Hereafter, waviness in a circumferential direction of the bottom 30B of the edge ring 30 will be described with reference to FIG. 3, along with use of the structure illustrated in FIG. 2A. FIGS. 3A and 3B schematically illustrate an example of waviness 30H in a circumferential direction of the bottom 30B of the edge ring 30 according to one embodiment.

FIG. 3A is a plan view of the edge ring 30 when viewed from the bottom 30B side. FIG. 3B schematically illustrates the waviness 30H in the circumferential direction of the bottom 30B of the edge ring 30, with reference to a virtual circle S1 with a radius r. The virtual circle S1 has a diameter (twice the radius r) ranging from an inner diameter to an outer diameter of the edge ring 30, where a given point on the central axis Ax of the edge ring 30 (central axis Ax of the processing chamber 10) is defined as the center O of the circle S1.

In FIG. 3A, the radius r of the virtual circle S1 from the center O has a diameter that is any diameter greater than or equal to the inner diameter and is less than or equal to the outer diameter of the edge ring 30. The inner diameter is determined based on the inner diameter surface 30C in FIGS. 2A and 2B. The outer diameter is determined based on the outer diameter surface 30D. In this example, for points on the circumference of the virtual circle S1, a point P1 is marked at an angle of 0° with respect to the point P1 and the center O, and points P1 to P8 are marked at 45° increments. However, the number of points on the circumference of the virtual circle S1 is not limited to being eight. The number of points on the circumference of the virtual circle S1 is sufficient to be two or more.

In this description, the waviness 30H in the circumferential direction of the edge ring 30, as illustrated in FIG. 3B, is defined by an absolute value indicative of a difference between a maximum value and a minimum value for vertical heights that are from given points on the circumference of the virtual circle S1, to the bottom 30B of the edge ring 30.

In the example of FIG. 3B, for the waviness 30H in the circumferential direction of the edge ring 30, heights from the bottom 30B of the edge ring 30 in the circumferential direction are schematically represented with reference to the virtual circle S1 having the radius r from the central axis Ax. However, the waviness in the circumferential direction of the edge ring 30 is not limited to the waviness 30H described above.

As an example of the vertical heights that are from the points P1 to P8, as illustrated in FIG. 3A, to the bottom 30B of the edge ring 30, the heights H1 to H8 are represented as illustrated in FIG. 3B, where the points P1 to P8 are marked on the circumference of the virtual circle S1, at 45° increments, and the point P1 is marked at an angle of 0° with respect to the center O and the point P1. The heights H1, H2, H4, and H6 indicate negative values, the height H3 indicates zero, and the heights H5, H7 and H8 indicate positive values. When the height H8 indicates a maximum value and the height H4 indicates a minimum value, the waviness 30H in the circumferential direction of the bottom 30B of the edge ring 30, which is assumed to have a given radius r from the center O, is calculated by |H8−H4|.

[Correlation Between Waviness in Circumferential Direction of Bottom of Edge Ring and Leakage of Heat Transfer Gas]

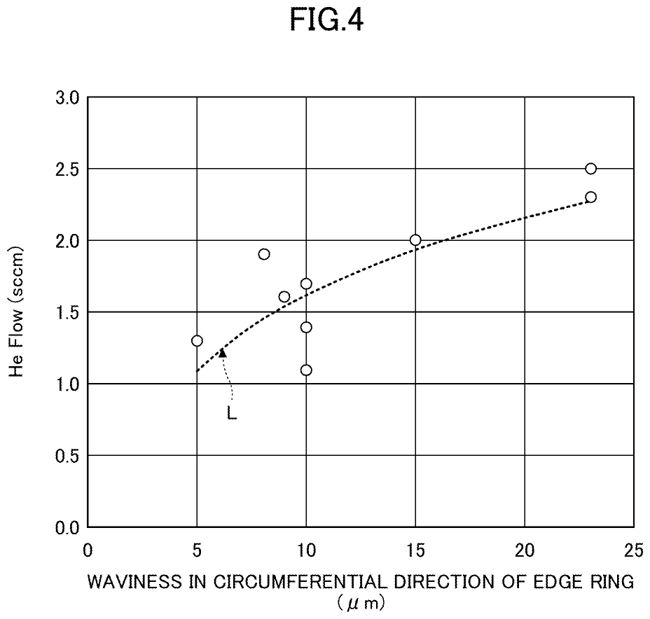

Hereafter, the correlation between the waviness 30H in the circumferential direction of the bottom 30B of the edge ring 30 and a leakage amount of the heat transfer gas will be described with reference to FIG. 4. FIG. 4 is a diagram illustrating an example of the correlation between the waviness 305 in the circumferential direction of the bottom 30B of the edge ring 30 and the leakage amount of the heat transfer gas according to one embodiment. In FIG. 4, the horizontal axis represents the waviness (μm) in the circumferential direction of the bottom 30B of the edge ring 30 that corresponds to a given virtual circle with the radius r. The vertical axis represents the leakage amount (sccm) of helium gas that is supplied to the gap G. The graph in FIG. 4 illustrates an example of test results obtained using the substrate processing apparatus 1 in FIG. 1. Note that the helium gas is an example of the heat transfer gas.

From the test results, it has been found that there is a correlation between the waviness 30H in the circumferential direction of the bottom 30B of the edge ring 30 and the leakage amount of the heat transfer gas, as represented by the dotted line L. In other words, it has been found that when the waviness 30H in the circumferential direction of the bottom 30B of the edge ring 30 is decreased within a given range, leakage of the heat transfer gas can be reduced.

Specifically, when the waviness in the circumferential direction of the bottom 30B of the edge ring 30 decreases from 20 μm, the leakage amount of the helium gas is decreased to approach 2.0 (sccm). From this result, it has been found that an attractive force of the edge ring 30 becomes stable, thereby enabling the leakage amount of the helium gas to be reduced.

Further, it has been found that when the waviness in the circumferential direction of the bottom 30B of the edge ring 30 decreases to be 15 μm or less, the attractive force of the edge ring 30 become more stable and thus the leakage amount of the helium gas can be reduced to be less than 2.0 (sccm).

In light of the results described above, for the edge ring 30 according to the present embodiment, the absolute value indicative of a given difference between the maximum value and the minimum value for vertical heights that are from given points on the circumference of the virtual circle S1, to the bottom 30B of the edge ring 30, is preferably set to be 20 μm or less. In such a manner, the bottom 30B of the edge ring 30 is stably attracted to the edge-ring mounting surface 25A of the electrostatic chuck 25, and thus the leakage amount of the heat transfer gas that is supplied to the gap G can be reduced.

More preferably, for the edge ring 30 according to the present embodiment, the absolute value indicative of a given difference between the maximum value and the minimum value for vertical heights that are from given points on the circumference of the virtual circle S1, to the bottom 30B of the edge ring 30, is set to be 15 μm or less. In such a manner, the bottom 30B of the edge ring 30 is more stably attracted to the edge-ring mounting surface 25A of the electrostatic chuck 25, and thus the leakage amount of the heat transfer gas that is supplied to the gap G can be further reduced. In other words, a predetermined upper limit for the absolute value described above is sufficient to be 20 μm or less, and more preferably 15 μm or less.

In the above description, as illustrated in FIG. 2A, the case where the bottom 30B of the edge ring 30 does not slope has been used. In this case, the virtual circle S1 is assumed to be a circle perpendicular to the central axis Ax.

In contrast, as illustrated in FIG. 2B, the bottom 30B of the edge ring 30 slopes such that the bottom 30B situated at the outer diameter surface 30D of the edge ring 30 is lower than the bottom 30B situated at the inner diameter surface 30C of the edge ring 30. In this case as well, the absolute value indicative of a given difference between a maximum value and a minimum value for vertical heights that are from given points on the circumference of the virtual circle S1, to the bottom 30B of the edge ring 30, defines the waviness in the circumferential direction of the bottom 30B of the edge ring 30.

As described above, from the correlation between the waviness in the circumferential direction of the bottom 30B of the edge ring 30 and the leakage amount of the heat transfer gas, the case of forming the edge ring 30 has been used, where the waviness 30H appearing in the circumferential direction of the bottom 30B of the edge ring 30, which is equivalent to a given virtual circle having the radius r, indicates 20 μm or less, and preferably 15 μm or less. In other words, the edge ring 30 is formed, such that the absolute value indicative of a given difference between the maximum value and the minimum value for given vertical heights that are from given points on the circumference of the virtual circle S1, to the bottom 30B of the edge ring 30, is set to be 20 μm or less, and preferably 15 μm or less. Note that as the radius r of a given virtual circle, half of a value in the range between the inner diameter and the outer diameter of the bottom 30B of the edge ring 30 can be adopted. Thus, even in a case of a given virtual circle having any radius r that is half of a given value among values in the range between the inner diameter and the outer diameter of the bottom 30B of the edge ring 30, the edge ring 30 is formed, such that waviness in the circumferential direction of the bottom 30B of the edge ring 30 indicates 20 μm or less, and preferably 15 μm or less. Accordingly, leakage of the heat transfer gas that is supplied to the gap G can be reduced.

[Correlation Between Waviness in Circumferential Direction of Edge-Ring Mounting Surface and Leakage of Heat Transfer Gas]

The above correlation between the waviness in circumferential direction of the bottom 30B of the edge ring 30 and the leakage amount of the heat transfer gas, as illustrated in FIG. 4, teaches that there is a correlation between waviness in the circumferential direction of the edge-ring mounting surface 25A, which is a surface facing the bottom 30B of the edge ring 30, and the leakage amount of the heat transfer gas.

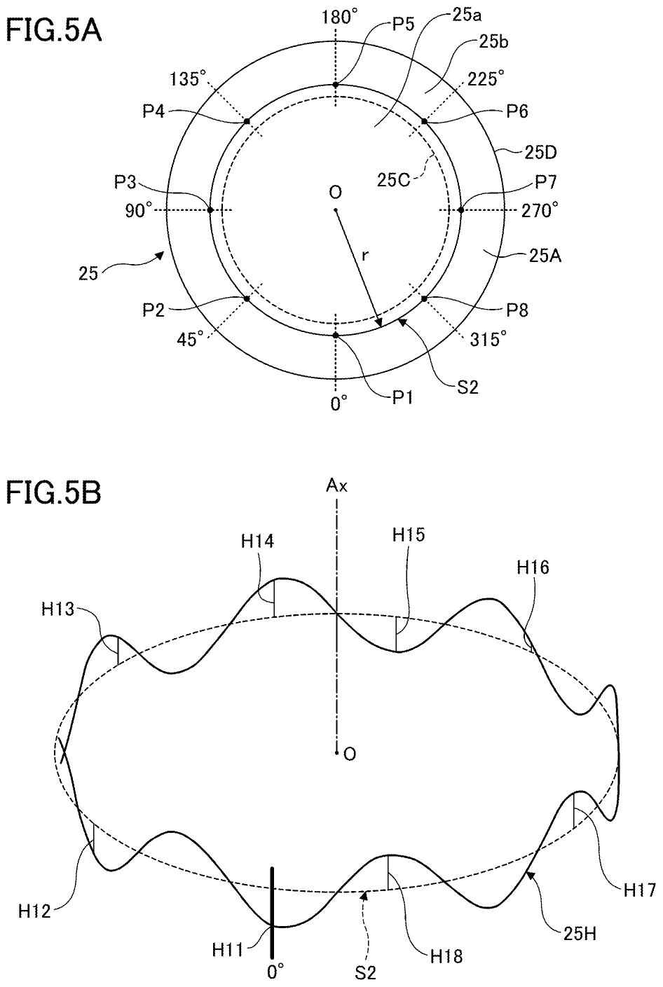

FIG. 5 schematically illustrates an example of waviness 25H in the circumferential direction of the edge-ring mounting surface 25A of the electrostatic chuck 25 according to one embodiment. FIG. 5A is a plan view of the stage 11 when viewed from the top side. FIG. 5B is a diagram illustrating vertical heights that are from points on the circumference of a virtual circle S2, to the edge-ring mounting surface 25A of the electrostatic chuck 25, with reference to a virtual circle S2 having a radius r. The virtual circle S2 has a diameter (twice the radius r) ranging from an inner diameter to an outer diameter of the edge-ring mounting surface 25A of the electrostatic chuck 25, where a given point on the central axis Ax of the stage 11 is defined as the center O of the circle S2.

In FIG. 5A, the radius r of the virtual circle S2 from the center O has a diameter that is any diameter greater than or equal to the inner diameter and is less than or equal to the outer diameter of the edge-ring mounting surface 25A. The inner diameter is determined based on the inner diameter surface 25C. The outer diameter is determined based on the outer diameter surface 25D.

FIG. 5B illustrates waviness 25H in the circumferential direction of the edge-ring mounting surface 25A of the electrostatic chuck 25, which corresponds to the virtual circle S2 having the radius r from the center O. For the waviness 25H in the circumferential direction of the edge-ring mounting surface 25A of the electrostatic chuck 25, vertical heights that are from given points on the circumference of the virtual circle S2, to the edge-ring mounting surface 25A of the electrostatic chuck 25, are measured, and an absolute value indicative of a difference between a maximum value and a minimum value for the measured heights is defined as the waviness 25H.

From test results in FIG. 4, the edge-ring mounting surface 25A of the stage 11 according to the present embodiment is preferably formed, such that the absolute value indicative of a given difference between the maximum value and the minimum value for vertical heights H11 to H18 that are from respective points on the circumference of the virtual circle S2, to the edge-ring mounting surface 25A of the electrostatic chuck 25, is less than or equal to 20 μm. More preferably, such an absolute value is set to be 15 μm or less. In such a manner, the edge ring 30 is stably attracted to the edge-ring mounting surface 25A of the electrostatic chuck 25, and thus the leakage amount of the heat transfer gas that is supplied to the gap G can be reduced.

As described above, from the correlation between the waviness in the circumferential direction of the edge-ring mounting surface 25A of the electrostatic chuck 25 and the leakage amount of the heat transfer gas, the case of forming the stage 11 has been described, where the waviness 25H appearing in the circumferential direction of the edge-ring mounting surface 25A of the electrostatic chuck 25, corresponding to a given virtual circle with the radius r, indicates 20 μm or less, and preferably 15 μm or less. In other words, the stage 11 is formed, such that the absolute value indicative of a given difference between the maximum value and the minimum value for given vertical heights that are from given points on the circumference of the virtual circle S2, to the edge-ring mounting surface 25A of the electrostatic chuck 25, is set to be 20 μm or less, and preferably 15 μm or less. Note that as the radius r of a given virtual circle, half of a value in the range between the inner diameter and the outer diameter of the edge-ring mounting surface 25A of the electrostatic chuck 25 can be adopted. Thus, even in a case of a given virtual circle with any radius r that is half of a given value among values in the range between the inner diameter and the outer diameter of the edge-ring mounting surface 25A of the electrostatic chuck 25, the stage 11 is formed, such that the waviness in the circumferential direction of the edge-ring mounting surface 25A of the electrostatic chuck 25 indicates 20 μm or less, and preferably 15 μm or less. Thus, leakage of the heat transfer gas that is supplied to the gap G can be reduced. In other words, a predetermined upper limit for the absolute value described above may be 20 μm or less, and more preferably 15 μm or less.

Note that the example of the case of the stage 11 having the electrostatic chuck 25 to electrostatically attract the substrate W to the substrate mounting surface 25W and to electrostatically attract the edge ring 30 to the edge-ring mounting surface 25A has been described. However, the stage is not limited to the example described above. In the present embodiment, for example, the stage 11 having a mechanical chuck to mechanically secure a given substrate W and the edge ring 30 can be also adopted, without having the electrostatic chuck 25.

[Correlation Between Space Provided Between Bottom of Edge Ring and Edge-Ring Mounting Surface of the Electrostatic Chuck, and Leakage Amount of Heat Transfer Gas]

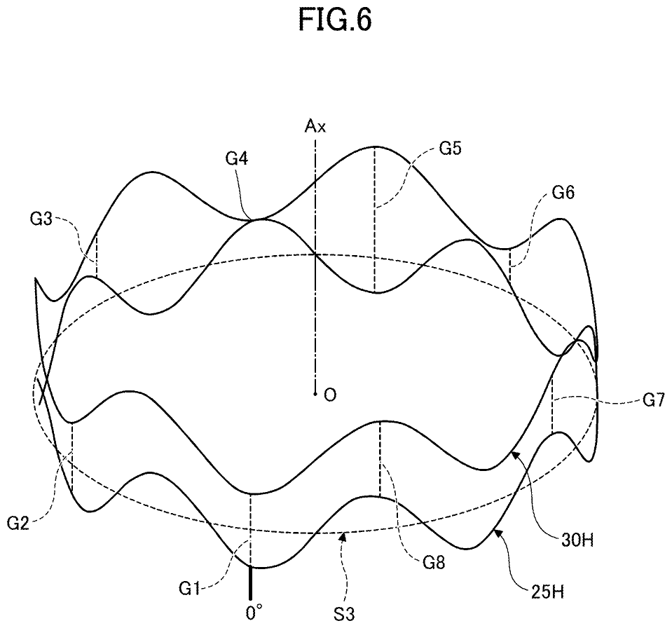

Hereafter, a gap provided between the bottom 30B and the edge-ring mounting surface 25A of the electrostatic chuck 25, and a leakage amount of the heat transfer gas will be described with reference to FIG. 6. FIG. 6 is a diagram schematically illustrating an example of the gap between the bottom 30B of the edge ring 30 and the edge-ring mounting surface 25A of the electrostatic chuck 25 according to one embodiment.

When the edge ring 30 for which the waviness 30H, as illustrated in FIG. 3B, appears in the circumferential direction of the bottom 30B of the edge ring is mounted on the fully flat edge-ring mounting surface 25A of the electrostatic chuck 25, the edge ring 30 is formed such that the waviness 30H indicates less than or equal to a predetermined upper limit. Likewise, when the edge ring 30 with a fully flat bottom 30B is mounted on the edge-ring mounting surface 25A of the stage 11 for which the waviness 25H, as illustrated in FIG. 5B, appears in the circumferential direction of the edge-ring mounting surface 25A of the stage 11, the stage 11 is formed such that the waviness 25H indicates less than or equal to a predetermined upper limit.

In the following description, a case in which the edge ring 30 for which the waviness 30H as illustrated in FIG. 3B appears is mounted on the edge-ring mounting surface 25A of the stage 11 for which the waviness 25H as illustrated in FIG. 5B appears, will be described, where the waviness 30H appears in the circumferential direction of the bottom 30B of the edge ring 30, and the waviness 25H appears in the circumferential direction of the edge-ring mounting surface 25A of the stage 11. In this case, a space illustrated in FIG. 6 is provided between the bottom 30B of the edge ring 30 and the edge-ring mounting surface 25A of the stage 11.

In this case, with reference to the waviness for each of the edge ring 30 and the edge-ring mounting surface 25A of the stage 11, a virtual circle S3 is assumed to have a radius r. The virtual circle S3 has a diameter (twice the radius r) ranging from a given inner diameter to a given outer diameter of the edge ring 30 or the edge-ring mounting surface 25A of the stage 11, where a given point on the central axis Ax is defined as the center O of the virtual circle S3. With reference to the virtual circle S3, as illustrated in FIG. 6, an absolute value indicative of a difference between a maximum value and a minimum value for distances G1 to G8 is calculated, where the distances G1 to G8 are each determined by a given amount of the space between the edge-ring mounting surface 25A of the stage 11 and the bottom 30B of the edge ring 30, and the amount of the space varies in accordance with a given point among points on the circumference of the virtual circle S3. The bottom 30B of the edge ring 30 and the edge-ring mounting surface 25A of the stage 11 are formed, such that the above absolute value is less than or equal to a predetermined upper limit. Note that the virtual circle S3 may be the same as the virtual circle S1 in FIGS. 3A and 3B or the virtual circle S2 in FIGS. 5A and 5B.

The absolute value indicative of a given difference between the maximum value and the minimum value for the distances G1 to G8 that are each determined by a given amount of the space between the edge-ring mounting surface 25A of the stage 11 and the bottom 30B of the edge ring 30, is calculated, where each of the distances G1 to G8 is set with respect to a given point among points (points P1 to P8 in FIG. 3A and FIG. 5A) that are marked on the circumference of the virtual circle S3. When the calculated absolute value is 20 μm or less, the force to attract the edge ring 30 to the edge-ring mounting surface 25A of the stage 11 becomes stable. Further, when the absolute value is 15 μm or less, the force to attract the edge ring 30 becomes more stable. Accordingly, leakage of the heat transfer gas that is supplied to the gap G can be reduced.

As described above, in the edge ring 30, the stage 11, and the substrate processing apparatus 1 according to the present embodiment, leakage of the heat transfer gas can be reduced.

While one or more embodiments of the present disclosure have been described using the edge ring, the stage, and the substrate processing apparatus, the embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

The substrate processing apparatus in the present disclosure is applicable to an automatic layer deposition (ALD) apparatus. Also, the substrate processing apparatus is applicable to any type among a capacitively coupled plasma (CCP), an inductively coupled plasma (ICP), a radial line slot antenna (RLSA), an electron cyclotron resonance plasma (ECR), and a helicon wave plasma (HWP).

The substrate processing apparatus is described using an example of a plasma processing apparatus. However, such an apparatus is not limited to the plasma processing apparatus. The substrate processing apparatus may be an apparatus in which a predetermined process (for example, deposition, an etch, or the like) is performed with respect to a substrate.

According to one aspect of the present disclosure, leakage of a heat transfer gas can be reduced.

What is claimed is:

1. An edge ring to be disposed to encircle a substrate, the edge ring comprising:
a bottom used to define vertical heights that are from points on the circumference of a virtual circle, to the bottom of the edge ring, the virtual circle having a radius from a first point that is placed on a central axis of the edge ring, the first point being defined as the center of the virtual circle, a diameter of the virtual circle ranging from an inner diameter to an outer diameter of the edge ring, and an absolute value indicative of a difference between a maximum value and a minimum value for the vertical heights being set to be less than or equal to a preset upper limit.

2. The edge ring according to claim 1, wherein the upper limit is 20 μm.

3. The edge ring according to claim 1, wherein the upper limit is 15 μm.

4. The edge ring according to claim 1, wherein the edge ring includes an inner diameter surface and an outer diameter surface, and
wherein the bottom of the edge ring slopes such that the bottom situated at the outer diameter surface of the edge ring is lower than the bottom situated at the inner diameter surface of the edge ring.

5. The edge ring according to claim 2, wherein the edge ring includes an inner diameter surface and an outer diameter surface, and
wherein the bottom of the edge ring slopes such that the bottom situated at the outer diameter surface of the edge ring is lower than the bottom situated at the inner diameter surface of the edge ring.

6. The edge ring according to claim 3, wherein the edge ring includes an inner diameter surface and an outer diameter surface,
wherein the bottom of the edge ring slopes such that the bottom situated at the outer diameter surface of the edge ring is lower than the bottom situated at the inner diameter surface of the edge ring.

7. A stage comprising:
a mounting surface for an edge ring to be disposed to encircle a substrate, the mounting surface being used to define vertical heights that are from points on the circumference of a virtual circle, to the mounting surface of the stage, the virtual circle having a radius from a first point that is placed on a central axis of the stage, the first point being defined as the center of the virtual circle, a diameter of the virtual circle ranging from an inner diameter to an outer diameter of the mounting surface of the stage, and an absolute value indicative of a difference between a maximum value and a minimum value for the vertical heights being set to be less than or equal to a preset upper limit.

8. The stage according to claim 7, further comprising an electrostatic chuck configured to electrostatically attract the edge ring to the mounting surface of the stage.

9. A substrate processing apparatus comprising:
an edge ring with a bottom, the edge ring being to be disposed to encircle a substrate; and
a stage with a mounting surface for the edge ring,
wherein a space is provided between the bottom of the edge ring and the mounting surface of the stage, with reference to a first virtual circle or a second virtual circle, the first virtual circle having a first radius from a first point that is placed on a central axis of the edge ring or the mounting surface of the stage, the second virtual circle having a second radius from the first point, a diameter of the first virtual circle ranging from an inner diameter to an outer diameter of the edge ring, a diameter of the second virtual circle ranging from an inner diameter to an outer diameter of the mounting surface of the stage, the first point being defined as the center of the first circle or the second circle, the space defining heights with respect to respective points on the circumference of the first circle or the second circle, and an absolute value indicative of a difference between a maximum value and a minimum value for the heights being set to be less than or equal to a preset upper limit.
